(19) United States
(12) Patent Application Publication
(10) Pub. No.: US 2026/0123250 A1
(43) Pub. Date: Apr. 30, 2026

(54) METHOD OF MANUFACTURING LIGHT CONTROL MEMBER, DISPLAY DEVICE INCLUDING LIGHT CONTROL MEMBER, AND ELECTRONIC DEVICE INCLUDING THE SAME

(71) Applicant: SAMSUNG DISPLAY CO., LTD., YONGIN-SI (KR)

(72) Inventor: DONGHA LEE, Yongin-si (KR)

(21) Appl. No.: 19/288,277

(22) Filed: Aug. 1, 2025

(30) Foreign Application Priority Data
Oct. 28, 2024 (KR) 10-2024-0148592

(51) Int. Cl. H10K 59/80; H10K 59/12

(52) U.S. Cl. CPC H10K 59/879; H10K 59/1201

(57) ABSTRACT

A method of manufacturing a light control member includes forming a preliminary lens portion by disposing a lens solution on a base layer. The method of manufacturing a light control member includes transferring the base layer on which the preliminary lens portion is formed to a chamber. The method of manufacturing a light control member includes forming a lens portion on the base layer by reducing an internal pressure of the chamber to not more than a pressure value for a time period. The time period is preset.

### CROSS-REFERENCE TO RELATED APPLICATION

This application claims priority under 35 U.S.C. §119 to Korean Patent Application No. 10-2024-0148592, filed on October 28, 2024, in the Korean Intellectual Property Office, the disclosure of which is incorporated by reference herein in its entirety.

### 1. Technical Field

The present disclosure relates to a display device having a light control member, and more specifically, to a method of manufacturing a light control member, a display device including the light control member, and an electronic device including the same.

### 2. Discussion of the Related Art

Display devices may be configured to receive information and display images. Display devices may be used as displays for small products such as mobile phones or for larger products such as televisions.

Display devices may include a plurality of pixels configured to receive electrical signals and emit light to display images externally. Each pixel may include a light-emitting element. For example, a light-emitting display device may include an organic light-emitting diode as a light-emitting element. For example, a light-emitting display device may include a thin-film transistor and an organic light-emitting diode on a substrate. The light-emitting diode may operate to emit light by itself.

Electronic devices, through included display devices, may function as visual interfaces for users.

### SUMMARY

According to embodiments of the disclosure, a method of manufacturing a light control member includes forming a preliminary lens portion by disposing a lens solution on a base layer. The method of manufacturing a light control member includes transferring the base layer on which the preliminary lens portion is formed to a chamber. The method of manufacturing a light control member includes forming a lens portion on the base layer by reducing an internal pressure of the chamber to not more than a pressure value for a time period. The time period is preset.

In some embodiments, the time period may be less than or equal to 100 seconds.

In some embodiments, the pressure value may be about 10⁻⁵ torr.

In some embodiments, the forming of the lens portion may include curing the preliminary lens portion by providing light of a wavelength band on the preliminary lens portion while the internal pressure of the chamber may be maintained at not more than the pressure value.

In some embodiment, the forming of the lens portion may be performed within a temperature range of about 25 °C to about 100 °C.

In some embodiments, the lens portion may have a semicircular shape.

In some embodiments, the forming of the preliminary lens portion may include spraying the lens solution onto the base layer by using inkjet printing.

In some embodiments, the lens solution may include a solvent and a base resin.

In some embodiments, the base resin may include at least one of polyurethane-based resin, polyester-based resin, polyvinyl chloride-based resin, polyvinyl acetate-based resin, cellulose-based resin, polyamide-based resin, polypropylene-based resin, polystyrene-based resin, or acrylic-based resin. The acrylic-based resin may include at least one of polymethyl methacrylate, polyhydroxyethylmethacrylate, or polycyclohexyl methacrylate.

In some embodiments, the solvent may include an ester-based compound.

In some embodiments, a boiling point of the solvent may be between 100 °C and 300 °C.

In some embodiments, the lens solution may further include at least one of TiO₂, ZrO₂, ZnO, Al₂O₃, or SiO₂.

According to embodiments of the disclosure, a method of manufacturing a display device includes preparing a display panel comprising an emission area and a non-emission area adjacent to the emission area. The method of manufacturing a display device includes forming a light control member on the display panel. The light control member may overlap the emission area. The forming of the light control member includes forming a preliminary lens portion by disposing a lens solution on a base layer. The forming of the light control member includes transferring the base layer on which the preliminary lens portion is formed to a chamber. The forming of the light control member includes forming a lens portion on the base layer by reducing an internal pressure of the chamber to not more than a pressure value for a time period. The time period is preset.

In some embodiments, the time period may be less than or equal to 100 seconds.

In some embodiments, the pressure value may be about 10⁻⁵ torr.

In some embodiments, the lens portion may have a semicircular shape.

In some embodiments, the forming of the preliminary lens portion may include spraying the lens solution onto the base layer by using inkjet printing.

In some embodiments, the lens solution may include a solvent and a base resin. A boiling point of the solvent may be between 100 °C and 300 °C.

In some embodiments, the lens solution may further include at least one of TiO₂, ZrO₂, ZnO, Al₂O₃, or SiO₂.

According to embodiments of the disclosure, an electronic device includes a controller configured to generate a scan input signal. An electronic device includes a power module configured to generate a scan input voltage. An electronic device includes a display panel including a display area and a peripheral area adjacent to the display area, the display area including a pixel circuit. An electronic device includes a scan driver disposed in the peripheral area and configured to receive the scan input signal and the scan input voltage, and output a scan signal to the pixel circuit. An electronic device includes a light control member including a lens portion, wherein the lens portion is formed by curing a lens solution on a base layer in a pressurized chamber for a preset time period prior to its placement in the light control member.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a plan view schematically illustrating a display device according to an embodiment of the disclosure;

FIG. 2 is a schematic diagram of an equivalent circuit of a pixel included in the display device of FIG. 1, according to an embodiment of the disclosure;

FIG. 3 is a cross-sectional view of a display device according to an embodiment of the disclosure;

FIG. 4 is an enlarged view of region A of FIG. 3, according to an embodiment of the disclosure;

FIG. 5 is a diagram for describing an inkjet printing method used in the process of forming a preliminary lens part, according to an embodiment of the disclosure;

FIG. 6 is a diagram for describing a preliminary lens part and a process of forming the same, according to an embodiment of the disclosure;

FIG. 7 is a diagram for describing a pressure condition in which a process of forming a lens part is performed, according to an embodiment of the disclosure;

FIG. 8 is a diagram for describing an example method of forming a lens part and a comparative example method;

FIG. 9 is a cross-sectional view illustrating a lens part formed through a method of manufacturing a light control member, according to an embodiment of the disclosure; and

FIG. 10 is a block diagram of an electronic device according to embodiments of the disclosure.

### DETAILED DESCRIPTION

The present invention will now be described more fully hereinafter with reference to the accompanying drawings, in which embodiments of the invention are shown. This invention may, however, be embodied in different forms and should not necessarily be construed as limited to the embodiments set forth herein. Effects and characteristics of the disclosure, and methods of accomplishing them will be apparent when referring to embodiments with reference to the drawings.

Although the terms “first”, “second”, etc. may be used herein to describe various elements, these elements, should not necessarily be limited by these terms. These terms may be used to distinguish one element from another element. Thus, a first element discussed below may be termed a second element without departing from the teachings of one or more embodiments. The description of an element as a “first” element might not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

The terminology used herein is for the purpose of describing example embodiments only and is not necessarily intended to be limiting of the present inventive concept. As used herein, the singular expressions “a,” “an,” and “the” may be intended to include the plural forms as well, unless the context clearly indicates otherwise.

The terms “include,” “comprises,” and/or “comprising”, when used herein, specify the presence of stated features, integers, steps, operations, elements, and/or components, but do not necessarily preclude the presence or addition of one or more other features, integers, steps, operations, elements, components, and/or groups thereof.

As used herein, when a layer, area, or element is referred to as being formed “on” another layer, area, or element, it can be directly or indirectly formed on the other layer, area, or element. For example, intervening layers, areas, or elements may be present.

Embodiments of the present disclosure are described with the understanding that the terms “connection” or “coupling” do not necessarily mean “direct and/or fixed connection or coupling” of two members, unless the context clearly indicates otherwise, and this does not necessarily preclude the disposition of other members between the two members.

Also, while each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

When a certain embodiment is implemented differently, a specific process sequence may be performed differently from a sequence described herein. For example, two consecutively described processes may be performed substantially at the same time or performed in an order opposite to the stated order.

Hereinafter, embodiments will be described in detail with reference to the accompanying drawings. When describing embodiments with reference to the accompanying drawings, the same or corresponding elements are denoted by the same reference numerals, and redundant descriptions thereof are omitted. To the extent that an element is not described in detail with respect to a figure, it may be understood that the element is at least similar to a corresponding element that has been described elsewhere within the present disclosure.

Traditionally, a light control member may include a lens part. However, during manufacturing, it may be challenging to preserve the curvature of the lens part. For example, the height and width of the lens part may change during manufacturing.

To resolve these challenges, a preliminary lens portion may be formed using inkjet printing and then dried in a high vacuum condition to form the lens portion. The drying of the preliminary lens portion may involve transferring the preliminary lens portion to a pressurized chamber and reducing the pressure of the chamber for a preset period of time.

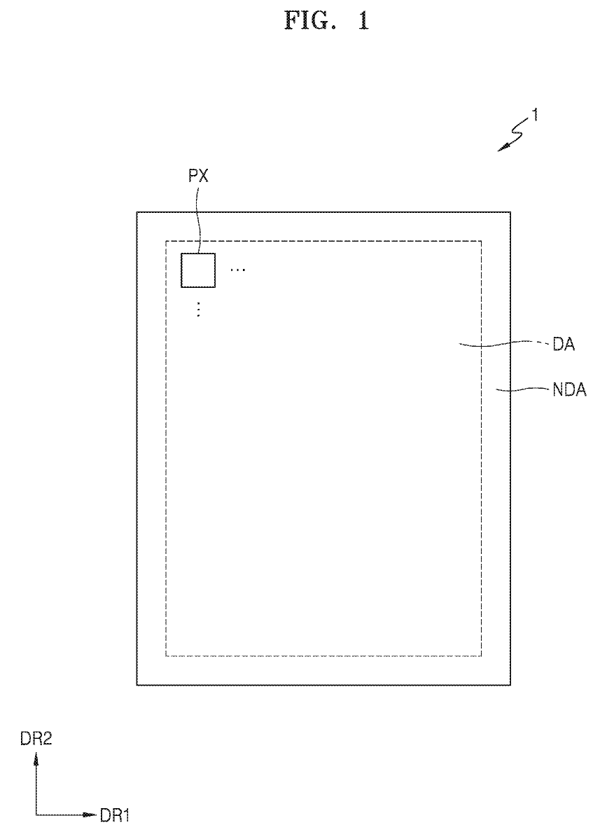

FIG. 1 is a plan view schematically illustrating a display device 1 according to an embodiment.

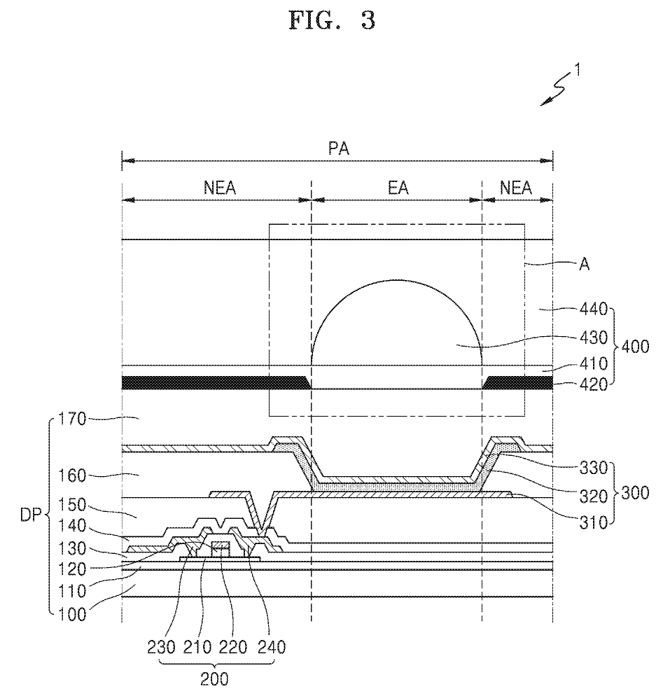

Referring to FIG. 1, the display device 1 may include a display area DA including a plurality of pixels PX, and a peripheral area NDA adjacent to the display area DA. In some embodiments, the peripheral area PA may be adjacent to at least one side of the display area DA. For example, the peripheral area NDA may completely surround the display area DA. In some embodiments, a substrate (see 100 of FIG. 3) included in the display device 1 may include the display area DA and the peripheral area NDA.

The plurality of pixels PX of the display device 1 may emit light of certain colors, and the display device 1 may display images by using the light emitted from the plurality of pixels PX. The plurality of pixels PX may externally emit, for example, red light, green light, blue light, or white light. Each of the pixels PX may refer to a sub-pixel and may include a display element and a pixel circuit connected to the display element. The display element may include an organic light-emitting diode or a quantum dot organic light-emitting diode.

The plurality of pixels PX may be disposed in a matrix form along a first direction DR1 and a second direction DR2. The first direction DR1 and the second direction DR2 may be defined as directions crossing each other. In some embodiments, the first direction DR1 and the second direction DR2 may intersect each other.

The display area DA may have a polygonal shape, including a rectangular shape, as illustrated in FIG. 1. For example, the display area DA may have a rectangular shape which extends longer in the second direction DR2 than in the first direction DR1. In embodiments, the display area DA may have other shapes, such as an elliptical shape or a circular shape.

The peripheral area NDA may be a non-display area in which the plurality of pixels PX are not disposed. A driver or the like configured to provide electrical signals or power to the plurality of pixels PX may be disposed in the peripheral area NDA. Pads to which various electronic devices or printed circuit boards may be electrically connected, may be disposed in the peripheral area NDA. The pads may be spaced apart from each other in the peripheral area NDA and may be electrically connected to printed circuit boards or integrated circuit devices.

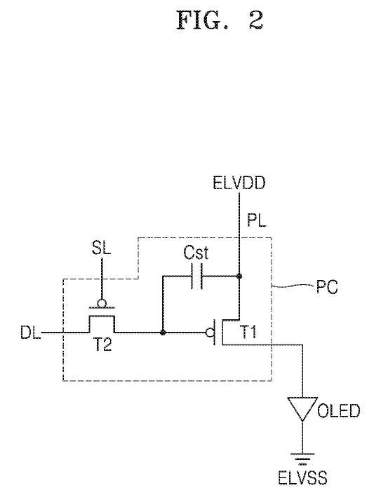

FIG. 2 is a schematic diagram of an equivalent circuit of the pixel PX included in the display device 1 of FIG. 1.

Referring to FIG. 2, the pixel PX may include a pixel circuit PC and an organic light-emitting diode OLED electrically connected to the pixel circuit PC.

The pixel circuit PC may include a first transistor T1, a second transistor T2, and a storage capacitor Cst. In some embodiments, the second transistor T2, may act as a switching transistor, and may be connected to a scan line SL and a data line DL. In some embodiments, the second transistor T2 may be configured to be turned on in response to a switching signal input from the scan line SL and transmit, to the first transistor T1, a data signal input from the data line DL. The storage capacitor Cst may have an end electrically connected to the second transistor T2 and another end electrically connected to a driving voltage line PL. In some embodiments, the storage capacitor Cst may be configured to store a voltage corresponding to a difference between a voltage received from the second transistor T2 and a driving power supply voltage ELVDD supplied to the driving voltage line PL.

The first transistor T1, which may act as a driving transistor, may be connected to the driving voltage line PL and the storage capacitor Cst. In some embodiments, the first transistor T1 may be configured to control an amount of a driving current flowing from the driving voltage line PL to the organic light-emitting diode OLED, according to a voltage value stored in the storage capacitor Cst. The organic light-emitting diode OLED may be configured to emit light with a certain luminance according to the driving current. An opposite electrode of the organic light-emitting diode OLED may be configured to receive an electrode power supply voltage ELVSS.

Although FIG. 2 illustrates that the pixel circuit PC includes two transistors and one storage capacitor, the disclosure is not necessarily limited thereto. For example, the number of transistors or the number of storage capacitors may be changed according to the design of the pixel circuit PC.

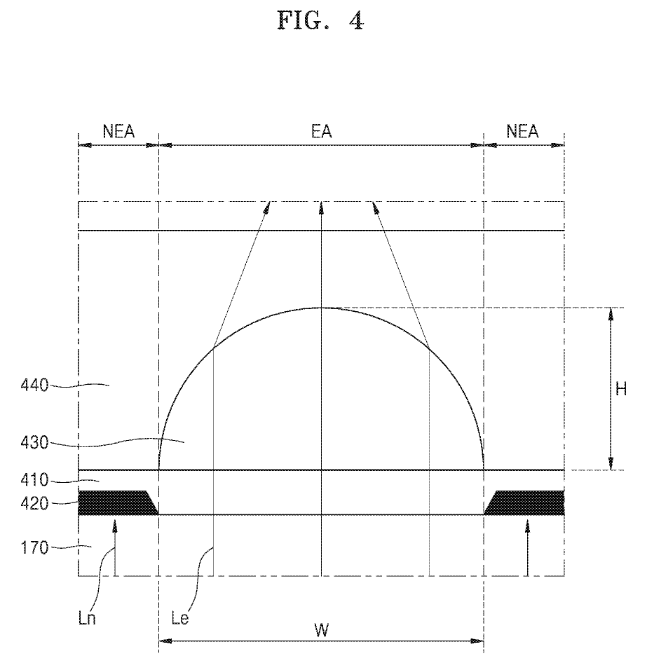

FIG. 3 is a cross-sectional view of a display device 1 according to an embodiment and FIG. 4 is an enlarged view of region A of FIG. 3.

Referring to FIG. 3, the display device 1 according to an embodiment may include a display panel DP and a light control member 400 disposed on the display panel DP. The display panel DP may be configured to substantially generate an image. The display panel DP may also be referred to as a display layer.

The display panel DP may include a substrate 100, a thin-film transistor (TFT) 200, a light-emitting element 300, and insulating layers. The TFT 200 and the light-emitting element 300 may be disposed on the substrate 100.

The substrate 100 may include various flexible or bendable materials, capable of being bent without being damaged. In some embodiments, the substrate 100 may include an insulating material. For example, the substrate 100 may include glass or polymer resin. In some embodiments, other modifications may be possible. For example, the substrate 100 may have a multilayer structure including two layers and a barrier layer between the two layers, wherein the two layers may include polymer resin and the barrier layer may include an inorganic material (for example, silicon oxide, silicon nitride, silicon oxynitride, or the like).

The substrate 100 may include a plurality of unit pixels PA. Each of the unit pixels PA may include an emission area EA and a non-emission area NEA. In some embodiments, the display panel DP may have the emission area EA and the non-emission area NEA.

In the emission area EA of each of the unit pixels PA, light of specific color may be emitted. For example, the light-emitting element 300 may be disposed in the emission area EA of each of the unit pixels PA. The light-emitting element 300 may emit light which indicates a color implemented by the corresponding unit pixel PA.

A buffer layer 110 may be disposed on the substrate 100. The buffer layer 110 may include an inorganic material, such as silicon nitride (SiNₓ), silicon oxynitride (SiOₓN_{y}), or silicon oxide (SiOₓ). The buffer layer 110 may be disposed on the substrate 100 and may increase the smoothness of the upper surface of the substrate 100 or may prevent or minimize infiltration of impurities from the substrate 100 or the like into a semiconductor layer 210 of the TFT 200.

The TFT 200 may be disposed on the buffer layer 110. The TFT 200 may include the semiconductor layer 210, a gate electrode 220, a source electrode 230, and a drain electrode 240. The semiconductor layer 210 may be disposed on the buffer layer 110.

The semiconductor layer 210 may include a semiconductor material. For example, the semiconductor layer 210 may include amorphous silicon or polycrystalline silicon. The semiconductor layer 210 may include an oxide semiconductor. For example, the semiconductor layer 210 may include indium gallium zinc oxide (IGZO).

The semiconductor layer 210 may include a source region, a drain region, and a channel region. The channel region may be disposed between the source region and the drain region. The channel region may have lower conductivity than the source region and the drain region. For example, the source region and the drain region may have a higher impurity concentration than the channel region.

A gate insulating layer 120 may be disposed on the semiconductor layer 210. In some embodiments, the gate insulating layer 120 may be disposed on a portion of the semiconductor layer 210. For example, the gate insulating layer 120 may be disposed on the channel region of the semiconductor layer 210. The source region and the drain region of the semiconductor layer 210 may be exposed by the gate insulating layer 120.

The gate insulating layer 120 may include an insulating material. For example, the gate insulating layer 120 may include an inorganic material, such as silicon nitride (SiNₓ), silicon oxynitride (SiOₓN_{y}), or silicon oxide (SiOₓ), and may include a single layer or a plurality of layers including the inorganic material described herein. The gate insulating layer 120 may be disposed between the semiconductor layer 210 and the gate electrode 220 and may ensure insulation between the semiconductor layer 210 and the gate electrode 220.

The gate electrode 220 may be disposed on the gate insulating layer 120. The gate electrode 220 may overlap the channel region of the semiconductor layer 210. The gate electrode 220 may include a conductive material. For example, the gate electrode 220 may include a low-resistance conductive material, such as molybdenum (Mo), aluminum (Al), copper (Cu), and/or titanium (Ti), and may include a single layer or a plurality of layers including the low-resistance conductive material described herein.

An interlayer insulating layer 130 may be disposed on the gate electrode 220. The interlayer insulating layer 130 may extend outward from the semiconductor layer 210. For example, the side surface of the semiconductor layer 210 and the side surface of the gate electrode 220 may be covered by the interlayer insulating layer 130. The interlayer insulating layer 130 may be in direct contact with the buffer layer 110 on the outer side of the semiconductor layer 210.

The interlayer insulating layer 130 may include an insulating material. For example, the interlayer insulating layer 130 may include an inorganic material, such as silicon nitride (SiNₓ), silicon oxynitride (SiOₓN_{y}), or silicon oxide (SiOₓ), and may include a single layer or a plurality of layers including the inorganic material described above.

The source electrode 230 and the drain electrode 240 may be disposed on the interlayer insulating layer 130. The source electrode 230 may be electrically connected to the source region of the semiconductor layer 210, and the drain electrode 240 may be electrically connected to the drain region of the semiconductor layer 210. The interlayer insulating layer 130 may include contact holes which partially expose the source region and the drain region of the semiconductor layer 210.

Each of the source electrode 230 and the drain electrode 240 may include a conductive material. For example, each of the source electrode 230 and the drain electrode 240 may include at least one material selected from copper, titanium, and aluminum. Each of the source electrode 230 and the drain electrode 240 may include a material which is different from a material of the gate electrode 220.

A lower protective layer 140 may be disposed on the source electrode 230 and the drain electrode 240. The lower protective layer 140 may prevent the TFT 200 from being damaged by external moisture and impact. For example, the TFT 200 may be covered by the lower protective layer 140.

A planarization layer 150 may be disposed on the lower protective layer 140. The planarization layer 150 may remove a step caused by the TFT 200. The surface of the planarization layer 150 facing the light-emitting element 300 may be a flat surface. For example, the surface of the planarization layer 150 facing the light-emitting element 300 may be substantially flat.

The lower protective layer 140 and the planarization layer 150 may expose a portion of the TFT 200. For example, the lower protective layer 140 may include a lower contact hole which partially exposes the drain electrode 240 of the TFT 200, and the planarization layer 150 may include an upper contact hole which overlaps the lower contact hole.

A first electrode 310 of the light-emitting element 300 may be electrically connected to the drain electrode 240 of the TFT 200 through the lower contact hole and the upper contact hole. For example, the first electrode 310 may extend along a sidewall of the lower contact hole and a sidewall of the upper contact hole and may be in direct contact with the drain electrode 240.

Each of the lower protective layer 140 and the planarization layer 150 may include an insulating material. The planarization layer 150 may include a material which is different from a material of the lower protective layer 140. For example, the lower protective layer 140 may include an inorganic insulating material, such as silicon oxide (SiO) and silicon nitride (SiN) and the planarization layer 150 may include an organic insulating material.

The light-emitting element 300 may be disposed on the planarization layer 150. The light-emitting element 300 may include the first electrode 310, an emission layer 320, and a second electrode 330, which are stacked on the substrate 100.

The first electrode 310 may include a conductive material. The first electrode 310 may have a relatively high reflectivity. For example, the first electrode 310 may include metal, such as aluminum (Al) or silver (Ag).

The first electrode 310 may have a multilayer structure. For example, the first electrode 310 may have a structure in which a reflective electrode including a material having relatively high reflectivity is disposed between transparent electrodes including a transparent conductive material, such as indium tin oxide (ITO) and indium zinc oxide (IZO).

The emission layer 320 may be configured to generate light with a luminance corresponding to a voltage difference between the first electrode 310 and the second electrode 330. For example, the emission layer 320 may include an emission material layer (EML) including an emission material. The emission material may include an organic material. For example, the display device according to an embodiment may be an organic light-emitting display device including the emission layer 320, and the emission layer 320 may include an organic material.

The second electrode 330 may include a conductive material. The second electrode 330 may be a transparent electrode. For example, the second electrode 330 may include a transparent conductive material, such as ITO and IZO. In the display device according to an embodiment, light generated by the emission layer 320 may be emitted through the second electrode 330.

The second electrode 330 may have a work function which is different from a work function of the first electrode 310. For example, the second electrode 330 may include metal, such as aluminum (Al). The second electrode 330 may have a multilayer structure.

The light-emitting elements 300 of the respective unit pixels PA may be driven independently. For example, the first electrode 310 of the light-emitting element 300 disposed on each of the unit pixels PA may be spaced apart from the first electrode 310 of the light-emitting element 300 disposed on the adjacent unit pixel PA.

A pixel defining layer 160 may be disposed between the first electrodes 310 adjacent to each other. The pixel defining layer 160 may define the emission area EA of each of the unit pixels PA. For example, the edge of the first electrode 310 disposed on each of the unit pixels PA may be covered by the pixel defining layer 160. A portion of the first electrode 310 exposed by the pixel defining layer 160 may overlap the emission area EA of the substrate 100. The pixel defining layer 160 may overlap the non-emission area NEA of the substrate 100. The emission layer 320 and the second electrode 330 of each of the light-emitting element 300 may be stacked on a portion of the first electrode 310 exposed by the pixel defining layer 160.

The pixel defining layer 160 may include an insulating material. For example, the pixel defining layer 160 may include an organic insulating material. The pixel defining layer 160 may include a material which is different from a material of the planarization layer 150.

An encapsulation layer 170 may be disposed on the light-emitting element 300. The encapsulation layer 170 may prevent the light-emitting element 300 from being damaged by external moisture and impact. The encapsulation layer 170 may include an insulating material. The encapsulation layer 170 may have a multilayer structure. For example, the encapsulation layer 170 may have a structure in which an inorganic insulating layer and an organic insulating layer are alternately stacked on the light-emitting element 300.

A step caused by the light-emitting element 300 may be removed by the encapsulation layer 170. For example, in the display device according to an embodiment, the surface of the encapsulation layer 170 opposite the substrate 100 may be a flat surface. For example, the surface of the encapsulation layer 170 opposite the substrate 100 may be substantially flat.

The encapsulation layer 170 may extend in the non-emission area NEA of the substrate 100. For example, the encapsulation layer 170 may include a portion overlapping the pixel defining layer 160. A thickness difference between the emission area EA and the non-emission area NEA on the substrate 100 may be eliminated by the encapsulation layer 170.

Although the insulating layers from the buffer layer 110 to the encapsulation layer 170, according to embodiments of the disclosure, have been described with reference to FIG. 3, the disclosure is not necessarily limited thereto. In embodiments, fewer insulating layers or more insulating layers may be disposed according to the structure of the TFT 200, the storage capacitor, and the structure of the light-emitting element 300.

The light control member 400 may be disposed on the display panel DP. The light control member 400 may be disposed on the encapsulation layer 170 of the display panel DP. The light control member 400 may reduce a viewing angle by controlling the light emitted from the light-emitting element 300 of each of the unit pixels PA. For example, the light control member 400 may include a base layer 410 and a lens part 430. In some embodiments, the lens part 430 may be a lens portion. For example, the lens part 430 may be referred to as a lens portion.

The base layer 410 may be disposed directly on the display panel DP. The expression “the base layer 410 is disposed directly on the display panel DP” may mean that no third element is disposed between the display panel DP and the base layer 410. For example, a separate adhesive member or adhesive layer may not be disposed between the base layer 410 and the display panel DP. In some embodiments, the base layer 410 may be coupled to the substrate 100, and the light-emitting element 300 may be covered by the encapsulation layer 170. In some embodiments, the base layer 410 may be coupled to the display panel DP through an adhesive member or adhesive layer. The adhesive member or adhesive layer may include a conventional adhesive or a sticking agent.

The base layer 410 may include an insulating material. For example, the base layer 410 may be an inorganic layer including at least one of silicon nitride, silicon oxynitride, or silicon oxide. For example, the base layer 410 may be an organic layer including epoxy resin, acrylic resin, or imide-based resin. The base layer 410 may have a single-layer structure or a multilayer structure.

The base layer 410 may include a black matrix 420. In an embodiment, the black matrix 420 may be disposed in close proximity to the display panel DP. For example, the black matrix 420 may be in direct contact with the encapsulation layer 170 of the display panel DP. Although FIG. 3 illustrates an embodiment in which the black matrix 420 is formed inside the base layer 410, the disclosure is not necessarily limited thereto, and the black matrix 420 may be formed as a layer which is separate from the base layer 410.

The black matrix 420 may be disposed in a portion of the base layer 410. The black matrix 420 may overlap the non-emission area NEA of the substrate 100. For example, the black matrix 420 may overlap the pixel defining layer 160. Accordingly, in the display device according to an embodiment, light Ln traveling from each of the unit pixels PA toward the adjacent unit pixel PA may be blocked by the black matrix 420.

For example, in the display device according to an embodiment, light may not be emitted through an area other than the emission area EA of each of the unit pixels PA. Therefore, the display device according to an embodiment may reduce a viewing angle.

The lens part 430 may be disposed on the base layer 410. The lens part 430 may overlap the emission area EA of the display panel DP. A width W of the lens part 430 may be equal to a width of the emission area EA. However, the disclosure is not necessarily limited thereto, and the width W of the lens part 430 may be greater than or less than the width of the emission area EA. In embodiments where the width W of the lens part 430 is different from the width of the emission area EA, the lens part 430 may be disposed so that the center of the lens part 430 coincides with the center of the emission area EA, and thus, the center of the lens part 430 may overlap the emission area EA.

The light-emitting element 300 may be disposed between the substrate 100 and the lens part 430. Accordingly, in the display device according to an embodiment, light Le emitted from the emission layer 320 of the light-emitting element 300 may be emitted externally through the lens part 430.

The lens part 430 may be in direct contact with the base layer 410. Accordingly, in the display device according to an embodiment, the surface of the lens part 430 facing the encapsulation layer 170 may be a flat surface. For example, the surface of the lens part 430 facing the encapsulation layer 170 may be substantially flat. Therefore, in the display device according to an embodiment, the focus of the lens part 430 may be adjusted. For example, the focus of the lens part 430 may be easily adjusted.

The shape of the lens part 430 may include a curved surface. For example, the vertex of the lens part 430 may have a curved surface. For example, the cross-sectional shape of the lens part 430 may include a curved surface, such as a circular shape or an elliptical shape. In an embodiment, the lens part 430 may have a hemispherical shape. For example, the cross-sectional shape of the lens part 430 may include a semicircular shape.

An aspect ratio of the lens part 430 may have a value selected within a range of 0.2 to 0.5. For example, the aspect ratio of the lens part 430 may be 0.5. The aspect ratio of the lens part 430 may be defined as a numerical value obtained by dividing the height H of the lens part 430 by the width W of the lens part 430. The height H of the lens part 430 may refer to the vertical distance from the base layer 410 to the vertex of the lens part 430, and the width W of the lens part 430 may refer to the width of the portion of the lens part 430 which is in contact with the base layer 410.

By adjusting the aspect ratio of the lens part 430 to the range of 0.2 to 0.5, the light Le emitted from the emission layer 320 of the light-emitting element 300 may be concentrated in a particular direction, for example a front direction. In some embodiments, the luminance of the display device in the front direction may be increased.

An upper planarization layer 440 may be disposed on the lens part 430. The upper planarization layer 440 may prevent the lens part 430 from being damaged by external impact. The upper planarization layer 440 may have a refractive index which is different from a refractive index of the lens part 430. For example, the refractive index of the upper planarization layer 440 may be less than the refractive index of the lens part 430. Accordingly, in the display device according to an embodiment, the light Le emitted externally through the lens part 430 may be concentrated within a space/area.

The upper planarization layer 440 may include an insulating material. For example, the upper planarization layer 440 may include an inorganic insulating material. In an embodiment, the upper planarization layer 440 may include the same material as the material of the base layer 410.

Although an embodiment in which the lens part 430 is formed on the base layer 410 has been described with reference to FIG. 3, the disclosure is not necessarily limited thereto. In a display device according to an embodiment, the base layer 410 may be omitted. For example, the lens part 430 may be formed directly on the display panel DP. In some embodiments where the lens part 430 is formed directly on the display panel DP, the lens part 430 may be formed by a process which is continuous with the process of forming the encapsulation layer 170 of the display panel DP.

In an embodiment, the light control member 400 may be formed through a separate process from the display panel DP and then coupled to the display panel DP. In some embodiments, the base layer 410 may function as a substrate in the process of forming the light control member 400. In embodiments where the light control member 400 is formed through a separate process from the display panel DP, the display device including the light control member 400 may prevent the light-emitting element 300 from being damaged by the process of forming the light control member 400.

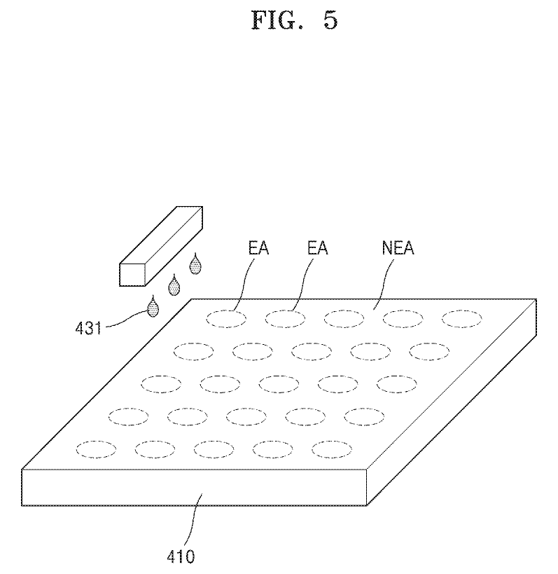

Hereinafter, a method of manufacturing the light control member 400 is described with reference to FIGS. 5 to 9 together with FIG. 3.

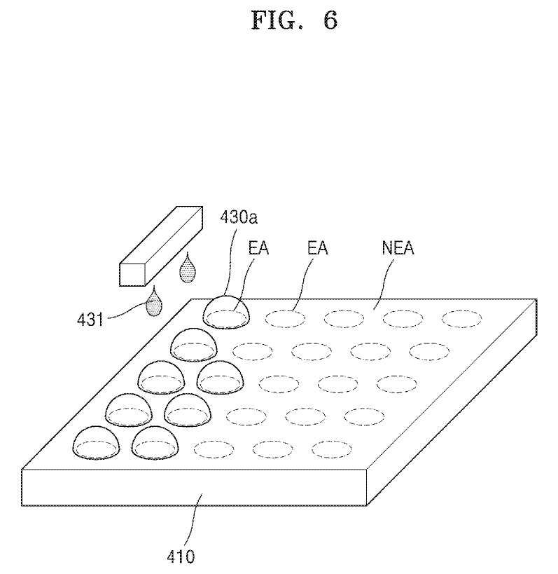

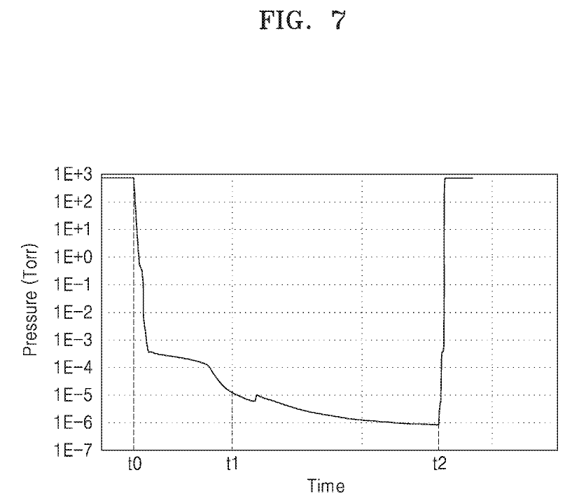

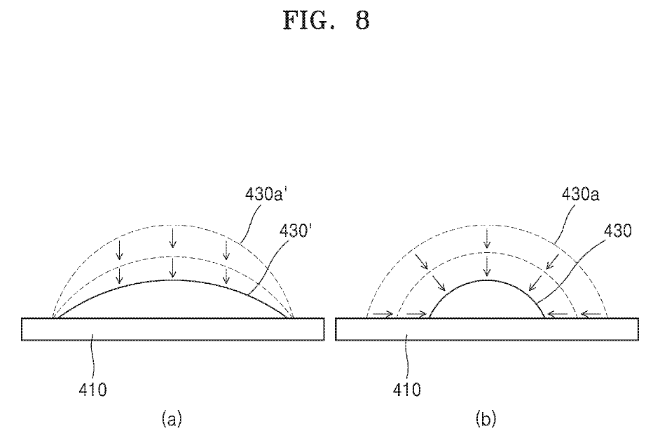

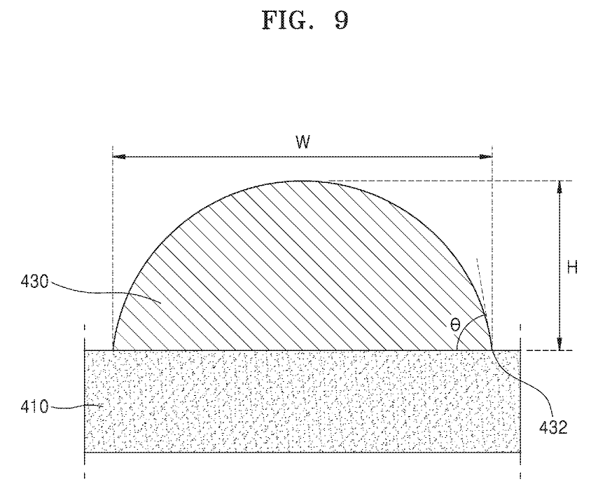

FIG. 5 is a diagram for describing an inkjet printing method used in the process of forming a preliminary lens part 430a, according to an embodiment, and FIG. 6 is a diagram for describing the preliminary lens part 430a and a process of forming the preliminary lens part 430a, according to some embodiments. FIG. 7 is a diagram for describing a pressure condition in which a process of forming a lens part 430 is performed, according to an embodiment, and FIG. 8 is a diagram for describing an example method of forming a lens part and a comparative example method. FIG. 9 is a cross-sectional view illustrating a lens part formed through a method of manufacturing a light control member, according to an embodiment.

As illustrated in FIG. 5, a base layer 410 in which an emission area EA and a non-emission area NEA are defined may be prepared. The emission area EA and the non-emission area NEA of the base layer 410 may be defined to overlap the emission area EA and the non-emission area NEA defined by the pixel defining layer 160 of the display panel DP.

In some embodiments, a lens solution 431 may be prepared. In some embodiments, lens solution 431 may be a material for forming the preliminary lens part 430a. In some embodiments, the preliminary lens part 430a may be a preliminary lens portion. For example, the preliminary lens part 430a may be referred to as a preliminary lens portion. The lens solution 431 may include a solvent and a base resin dispersed in the solvent. The lens solution 431 may be prepared in a solution or in a colloid state including a solvent.

For example, the base resin may include at least one of polyurethane-based resin, polyester-based resin, polyvinyl chloride-based resin, polyvinyl acetate-based resin, cellulose-based resin, polyamide-based resin, polypropylene-based resin, polystyrene-based resin, or acrylic-based resin. Acrylic-based resin may include polymethyl methacrylate, polyhydroxyethylmethacrylate, or polycyclohexyl methacrylate. However, this is only an example and the material of the base resin is not necessarily limited thereto.

The base resin may include a liquid monomer and an initiator. For example, the monomer may be a urethane monomer, an ethylene monomer, an acrylic monomer, an epoxy monomer, or an ester monomer.

The solvent refers to a medium in which the base resin may be dispersed. The solvent may be in a liquid state. In some embodiments, the solvent may have a viscosity sufficient to be discharged through a nozzle of an inkjet printing device in a liquid state. The solvent may be a material which is easily volatilized. For example, a boiling point of the solvent may be about 100 °C to about 300 °C. In some embodiments, the boiling point of the solvent may be between 100 °C and 300 °C. The solvent may be removed from the preliminary lens part 430a as the lens part 430 is formed.

For example, the solvent may be an ester-based compound, such as diethylene glycol dibenzoate, triethyl citrate, a phthalate-based solvent, benzyl butyl phthalate, bis(2-ethlyhexyl) phthalate, bis(2-ethylhexyl) isophthalate, ethyl phthalyl ethyl glycolate, n-butyl benzoate, or dimethyl phthalate. However, the disclosure is not necessarily limited thereto, and any organic solvent which might not react with the base resin may be used.

The lens solution 431 may further include an inorganic material. The inorganic material included in the lens solution 431 may control a refractive index range of the lens part 430. For example, the lens solution 431 may include an inorganic material having a high refractive index, such as titanium dioxide (TiO₂), zinc oxide (ZnO), zirconium dioxide (ZrO₂), or titanium carbide (TiC). In some embodiments, the lens solution 431 may include an inorganic material, such as aluminum oxide (Al₂O₃), yttrium oxide (Y₂O₃), or silicon dioxide (SiO₂).

As illustrated in FIG. 6, the preliminary lens part 430a may be formed by providing the lens solution 431 on the surface of the base layer 410. The lens solution 431 may be provided on the base layer 410 by an inkjet printing method or a dispensing method. For example, the lens solution 431 may be deposited on the base layer 410. The following description is given focusing on an embodiment in which the lens solution 431 is sprayed onto the base layer 410 through an inkjet printing process.

The lens solution 431 may be sprayed onto the base layer 410 through a printing process using an inkjet printing device. The “printing” of the lens solution 431 may refer to discharging or spraying the lens solution 431 onto a certain area by using the inkjet printing device. The lens solution 431 may be sprayed through a nozzle of an inkjet head included in the inkjet printing device. The lens solution 431 discharged through the nozzle may settle on the surface of the base layer 410. The lens solution 431 which is settled on the surface of the base layer 410 may form the preliminary lens part 430a having a hemispherical shape.

The lens solution 431 may be printed to correspond to the emission area EA of the base layer 410. For example, the preliminary lens part 430a may be formed on the emission area EA of the base layer 410. In some embodiments, the width of the surface of the preliminary lens part 430a which is in contact with the base layer 410 may be greater than the width of the emission area EA of the base layer 410, but the disclosure is not necessarily limited thereto. A plurality of preliminary lens parts 430a may be formed in the respective emission areas EA of the base layer 410. The plurality of preliminary lens parts 430a may be spaced apart from each other.

The base layer 410 on which the preliminary lens part 430a is formed may be transferred to a chamber, for example, to a pressurized chamber. The chamber may provide vacuum state and light of a first wavelength band to the preliminary lens part 430a. For example, the light of a first wavelength band may be provided to the preliminary lens part 430a. The vacuum state and the light of the first wavelength band provided to the preliminary lens part 430a may be provided simultaneously. For example, the vacuum state and the light of the first wavelength band provided to the preliminary lens part 430a may be provided sequentially. For example, the vacuum state may be provided to the preliminary lens part 430a, and then, the light of the first wavelength band may be provided after a certain period of time.

As illustrated in FIG. 7, the chamber may reduce the internal pressure of the chamber to a first pressure or lower for a first time period. For example, the chamber may reduce the internal pressure of the chamber to a first pressure or lower for a first time t1 preset from a time point t0. The time point t0 may be a time at which the base layer 410 on which the preliminary lens part 430a is formed is transferred to the chamber. The first time t1 may have a value less than or equal to 100 seconds and the first pressure may be about 10⁻⁵ torr. For example, the chamber may make a high vacuum state by reducing the internal pressure of the chamber to 10⁻⁵ torr or less for a short time of up to 100 seconds.

In some embodiments, the chamber may maintain the internal pressure at the first pressure or less from the first time t1 to a second time t2 and may maintain the interior of the chamber in a high vacuum state. After the preliminary lens part 430a is transferred to the chamber, the solvent may be volatilized and dried within the chamber of which the pressure is reduced until the second time t2. In embodiments where the internal pressure of the chamber is reduced, the temperature inside the chamber may be in a range of about 25 °C to about 100 °C. For example, in embodiments where the internal pressure of the chamber is reduced, the temperature inside the chamber may be within a temperature range of 25 °C to 100 °C.

In some embodiments, the chamber may cure the preliminary lens part 430a by providing the light of the first wavelength band to the preliminary lens part 430a transferred into the chamber. The first wavelength band may be an ultraviolet (UV) band.

In an embodiment, the process of providing the light of the first wavelength band to the preliminary lens part 430a may be performed simultaneously with the process of reducing the internal pressure of the chamber to the first pressure or less. In some embodiments, the preliminary lens part 430a may start drying and curing simultaneously. In some embodiments, the process of providing the light of the first wavelength band to the preliminary lens part 430a may be performed after the second time t2 when the process of reducing the internal pressure of the chamber is completed.

In some embodiments, the process of providing the light of the first wavelength band to the preliminary lens part 430a may be performed after the process of reducing the internal pressure of the chamber to the first pressure or less. For example, the curing of the preliminary lens part 430a may be performed after the first time t1, which is the time point when the internal pressure of the chamber is reduced to the first pressure or less, and may be performed while the internal pressure of the chamber is maintained at the first pressure or less. At the first time t1, the preliminary lens part 430a may be dried to some extent, and the process time may be shortened by simultaneously performing the remaining drying and curing of the preliminary lens part 430a.

In FIG. 8, structure (a) illustrates a process of forming a lens part 430' without reducing an internal pressure of a chamber as a comparative example. As illustrated in structure (a) of FIG. 8, in embodiments where a preliminary lens part 430a' is dried without reducing the internal pressure of the chamber, the apex and edge portions of the preliminary lens part 430a' are dried at different speeds. In the preliminary lens part 430', a lens solution volatilizes faster at the edge portion in contact with a base layer 410 than at other portions. Accordingly, the shape of the lens part 430' which has been dried may have little or insignificant change in width from the preliminary lens part 430a' and a shape which may be only lower in height. The curvature of the lens part 430' may be less than the curvature of the preliminary lens part 430a'.

In embodiments where the lens part 430 is formed by using the method of manufacturing the light control member 400, the curvature of the preliminary lens part 430a might not decrease during drying, as illustrated in structure (b) of FIG. 8. For example, in embodiments where the internal pressure of the chamber is quickly reduced to the first pressure or less for the preset first time t1 and the preliminary lens part 430a is dried, a lens solution volatilization effect concentrated on the edge of the preliminary lens part 430a might not occur, and the lens solution may uniformly volatilize over the entire area exposed externally. In some embodiments, the curvature of the lens part 430 formed by drying the preliminary lens part 430a may be equal to the curvature of the preliminary lens part 430a.

In the lens part 430 manufactured according to an embodiment, the aspect ratio which is the ratio of the width W of the lens part 430 to the height H of the lens part 430 may be a desired value, as illustrated in FIG. 9. In some embodiments, a contact angle θ of the lens part 430 may be a desired value. The contact angle θ of the lens part 430 may be defined as an angle formed by the base layer 410 and a tangent line of a contact portion 432 of the lens part 430. For example, the contact angle θ of the lens part 430 may have a value within a range of about 50° to 90°. For example, the contact angle θ of the lens part 430 may be 90°.

In some embodiments, the light control member 400 may control the contact angle θ of the lens part 430 according to the purpose. For example, the lens part 430 having a high contact angle θ may be formed.

A method of manufacturing the display device 1 including the light control member 400, according to an embodiment, may include preparing the display panel DP including the emission area EA and the non-emission area NEA. The light control member 400 may be formed on the display panel DP so as to overlap the emission area EA. Because the method of manufacturing the light control member 400, according to an embodiment, has been described above, a more detailed description thereof is omitted. The description of the method of manufacturing the display device 10 may refer to description of embodiments of the method of manufacturing the display device 1 and description of embodiments of the light control member 400 provided above.

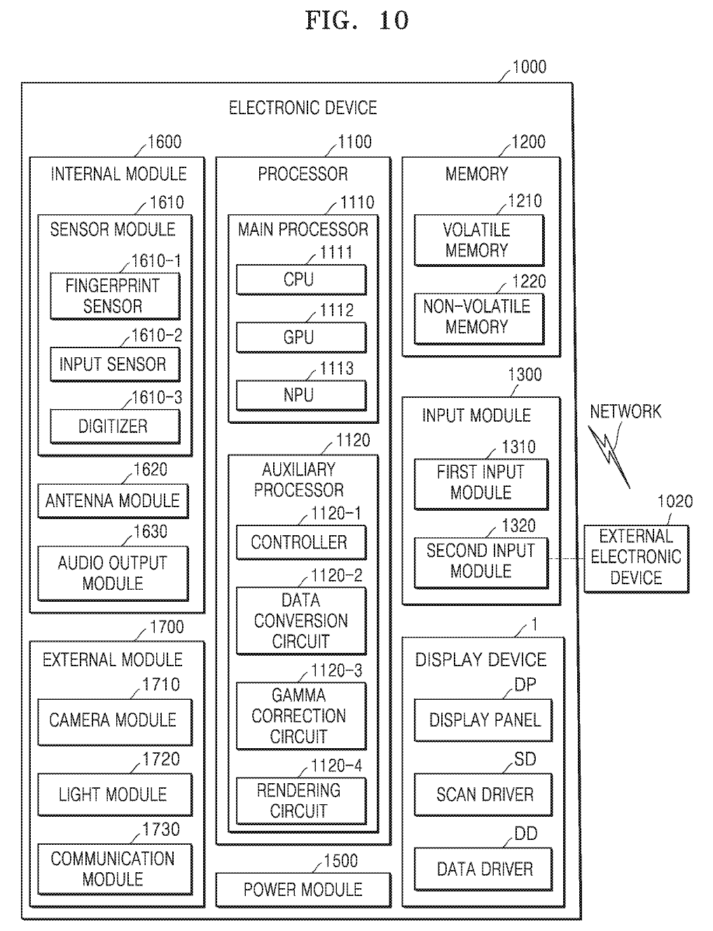

FIG. 10 is a block diagram of an electronic device 1000 according to embodiments.

The electronic device 1000 may output a variety of information through a display device 1 within an operating system. In embodiments where a processor 1100 executes an application stored in a memory 1200, the display device 1 may provide information corresponding to the application to a user through a display panel DP.

The processor 1100 may obtain external input through an input module 1300 or a sensor module 1610 and execute an application corresponding to the external input. For example, in embodiments where the user selects a camera icon displayed on the display panel DP, the processor 1100 may obtain user input through an input sensor 1610-2 and activate a camera module 1710. The processor 1100 may transmit, to the display device 1, image data corresponding to a captured image obtained through the camera module 1710. The display device 1 may display an image corresponding to the captured image on the display panel DP.

In embodiments where personal information authentication is performed on the display device 1, a fingerprint sensor 1610-1 may obtain input fingerprint information as input data. The processor 1100 may compare the input data obtained through the fingerprint sensor 1610-1 with authentication data stored in the memory 1200 and execute an application based on a comparison result. The display device 1 may display information executed according to the logic of the application on the display panel DP.

In embodiments where the user selects a music streaming icon displayed on the display device 1, the processor 1100 may obtain user input through the input sensor 1610-2 and activate a music streaming application stored in the memory 1200. In embodiments where a music execution command is input in the music streaming application, the processor 1100 may activate an audio output module 1630 to provide, to the user, audio information corresponding to the music execution command.

The operation of the electronic device 1000 has been briefly described above. Hereinafter, the configuration of the electronic device 1000 is described in more detail. Some components of the electronic device 1000 described below may be integrated and provided as one component, and in some embodiments, a single component may be separated into two or more components.

Referring to FIG. 10, the electronic device 1000 may communicate with an external electronic device 1020 over a network (e.g., a short-range wireless communication network or a long-range wireless communication network). According to an embodiment, the electronic device 1000 may include the processor 1100, the memory 1200, the input module 1300, the display device 1, a power module 1500, an internal module 1600, and an external module 1700. According to an embodiment, at least one of the components described above may be omitted from the electronic device 1000, or one or more other components may be added to the electronic device 1000. According to an embodiment, some components described above (e.g., the sensor module 1610, an antenna module 1620, or the audio output module 1630) may be integrated into another component (e.g., the display device 1).

The processor 1100 may execute software to control at least one other component (e.g., a hardware or software component) of the electronic device 1000 connected to the processor 1100 and perform various data processing or operations. According to an embodiment, as at least part of data processing or operations, the processor 1100 may store commands or data received from another component (e.g., the input module 1300, the sensor module 1610, or a communication module 1730) in a volatile memory 1210, process the commands or data stored in the volatile memory 1210, and store resulting data in a non-volatile memory 1220.

The processor 1100 may include a main processor 1110 and an auxiliary processor 1120. The main processor 1110 may include at least one of a central processing unit (CPU) 1111 or an application processor (AP). The main processor 1110 may further include at least one of a graphic processing unit (GPU) 1112, a communication processor (CP), or an image signal processor (ISP). The main processor 1110 may further include a neural processing unit (NPU) 1113. The NPU 1113 may be a processor specialized in processing an artificial intelligence model. The artificial intelligence model may be generated through machine learning. The artificial intelligence model may include a plurality of artificial neural network layers. The artificial intelligence model may be a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more thereof, but the disclosure is not necessarily limited to the above examples. The artificial intelligence model may additionally or alternatively include a software structure in addition to the hardware structure. At least two of the processing units and processors described above may be implemented as a single integrated configuration (e.g., a single chip), or the processing units and processors described above may be implemented as independent configurations (e.g., a plurality of chips).

The auxiliary processor 1120 may include a controller 1120-1. The controller 1120-1 may include an interface conversion circuit and a timing control circuit. The controller 1120-1 may receive an image signal from the main processor 1110, convert the data format of the image signal to match the interface specification with the display device 1, and output the image data. The controller 1120-1 may output various control signals required to drive the display device 1.

The auxiliary processor 1120 may further include a data conversion circuit 1120-2, a gamma correction circuit 1120-3, a rendering circuit 1120-4, or the like. The data conversion circuit 1120-2 may receive image data from the controller 1120-1, compensate for the image data so that the image is displayed at a desired luminance according to characteristics of the electronic device 1000 or a user's settings, or convert the image data so as to reduce power consumption or compensate for afterimages. The gamma correction circuit 1120-3 may convert image data or gamma reference voltages so that the image displayed on the electronic device 1000 has desired gamma characteristics. The rendering circuit 1120-4 may receive image data from the controller 1120-1 and render the image data by taking into account the pixel layout of the display panel DP applied to the electronic device 1000. At least one of the data conversion circuit 1120-2, the gamma correction circuit 1120-3, or the rendering circuit 1120-4 may be integrated into another component (e.g., the main processor 1110 or the controller 1120-1). At least one of the data conversion circuit 1120-2, the gamma correction circuit 1120-3, or the rendering circuit 1120-4 may be integrated into a data driver DD described below.

The memory 1200 may store various data used by at least one component of the electronic device 1000 (e.g., the processor 1100 or the sensor module 1610) and input data or output data for commands related thereto. The memory 1200 may include at least one of the volatile memory 1210 or the non-volatile memory 1220.

The input module 1300 may receive commands or data to be used in the components of the electronic device 1000 (e.g., the processor 1100, the sensor module 1610, or the audio output module 1630) from a source external to the electronic device 1000 (e.g., a user or an external electronic device 1020).

The input module 1300 may include a first input module 1310 configured to receive input commands or data from the user and a second input module 1320 configured to receive input commands or data from the external electronic device 1020. The first input module 1310 may include a microphone, a computer mouse, a keyboard, a key (e.g., a button), or a pen/stylus (e.g., a passive pen or an active pen). The second input module 1320 may support a designated protocol which is connectable to the external electronic device 1020 in a wired or wireless manner. According to an embodiment, the second input module 1320 may include a high-definition multimedia interface (HDMI), a universal serial bus (USB) interface, a secure digital (SD) card interface, or an audio interface. The second input module 1320 may include a connector which is physically connectable to the external electronic device 1020, for example, an HDMI connector, a USB connector, an SD card connector, or an audio connector (e.g., a headphone connector).

The display device 1 may provide visual information to the user. The display device 1 may include the display panel DP, a scan driver SD, and a data driver DD. The display device 1 may further include a window, a chassis, and a bracket so as to protect the display panel DP.

The display device 1, the display panel DP, and the like, which have been described with reference to FIG. 10, refer to the display device 1, the display panel DP, and the like, which have been described with reference to FIGS. 1 to 9. Accordingly, descriptions of the display device 1, the display panel DP, and the like, which are identical to or redundant with those provided above, may be omitted. To the extent that an element is not described in detail with respect to a figure, it may be understood that the element is at least similar to a corresponding element that has been described elsewhere within the present disclosure.

The display panel DP may include a liquid crystal display panel, an organic light-emitting display panel, or an inorganic light-emitting display panel, and the type of the display panel DP is not necessarily limited thereto. The display panel DP may be of a rigid type or of a flexible type which is rollable or foldable, without being damaged. The display device 1 may further include a supporter, a bracket, or heat dissipation member/layer, which supports the display panel DP.

The scan driver SD may be mounted on the display panel DP as a driving chip. In some embodiments, the scan driver SD may be integrated into the display panel DP. For example, the scan driver SD may include an amorphous silicon TFT gate driver circuit (ASG), a low-temperature polycrystalline silicon (LTPS) TFT gate driver circuit, or an oxide semiconductor TFT gate driver circuit (OSG), which is embedded in the display panel DP. The scan driver SD may receive a control signal from the controller 1120-1 and output scan signals to the display panel DP in response to the control signal.

The display panel DP may further include an emission driver. The emission driver may output an emission control signal to the display panel DP in response to the control signal received from the controller 1120-1. The emission driver may be formed separately from the scan driver SD or may be integrated into the scan driver SD.

The data driver DD may receive a control signal from the controller 1120-1, convert image data into analog voltages (e.g., data voltages) in response to the control signal, and then output the data voltages to the display panel DP.

The data driver DD may be integrated into another component (e.g., the controller 1120-1). The functions of the interface conversion circuit and the timing control circuit of the controller 1120-1 may be integrated into the data driver DD.

In some embodiments, the display device 1 may include an emission driver and a voltage generation circuit. The voltage generation circuit may output various voltages required to drive the display panel DP.

The power module 1500 may supply power to the components of the electronic device 1000. The power module 1500 may include a chargeable battery which may be charged with a power supply voltage. The battery may include a non-rechargeable primary battery, a rechargeable secondary battery, or a fuel cell. The power module 1500 may include a power management integrated circuit (PMIC). The PMIC may provide optimized power to each of the modules described herein. The power module 1500 may include a wireless power transmitter/receptor electrically connected to the battery. The wireless power transmitter/receptor may include a plurality of coil-type antenna radiators.

The electronic device 1000 may further include the internal module 1600 and the external module 1700. The internal module 1600 may include the sensor module 1610, the antenna module 1620, and the audio output module 1630. The external module 1700 may include the camera module 1710, a light module 1720, and the communication module 1730.

The sensor module 1610 may detect input by the user's body or input by the pen/stylus of the first input module 1310 and generate an electrical signal or a data value corresponding to the input. The sensor module 1610 may include at least one of the fingerprint sensor 1610-1, the input sensor 1610-2, or a digitizer 1610-3.

The fingerprint sensor 1610-1 may generate a data value corresponding to the user's fingerprint. The fingerprint sensor 1610-1 may include at least one of an optical fingerprint sensor or a capacitive fingerprint sensor.

The input sensor 1610-2 may generate a data value corresponding to coordinate information of the input by the user's body or the input by the pen/stylus. The input sensor 1610-2 may generate a data value based on an amount of change in electrostatic capacitance by the input. The input sensor 1610-2 may detect input by the passive pen/stylus, or may transmit and receive data to and from the active pen/stylus.

The input sensor 1610-2 may also measure biometric signals, such as blood pressure, moisture, or body fat. For example, in embodiments where the user touches a part of user’s body to a sensor layer or a sensing panel and does not move for a certain time, the input sensor 1610-2 may detect biometric signals based on a change in electric field caused by the part of user’s body and output information desired by the user to the display device 1.

The digitizer 1610-3 may generate a data value corresponding to coordinate information input by the pen/stylus. The digitizer 1610-3 may generate a data value based on an amount of change in electromagnetic field by the input. The digitizer 1610-3 may detect input by the passive pen/stylus, or may transmit and receive data to and from the active pen/stylus.

At least one of the fingerprint sensor 1610-1, the input sensor 1610-2, or the digitizer 1610-3 may be implemented as the sensor layer formed on the display panel DP through a continuous process. The fingerprint sensor 1610-1, the input sensor 1610-2, and the digitizer 1610-3 may be disposed above the display panel DP. One of the fingerprint sensor 1610-1, the input sensor 1610-2, and the digitizer 1610-3, for example, the digitizer 1610-3 may be disposed below the display panel DP.

At least two of the fingerprint sensor 1610-1, the input sensor 1610-2, or the digitizer 1610-3 may be integrated into a single sensing panel through the process described above. In embodiments where at least two of the fingerprint sensor 1610-1, the input sensor 1610-2, or the digitizer 1610-3 are integrated into a single sensing panel, the sensing panel may be disposed between the display panel DP and the window disposed above the display panel DP. According to an embodiment, the sensing panel may be disposed on the window and the location of the sensing panel is not necessarily limited thereto.

At least one of the fingerprint sensor 1610-1, the input sensor 1610-2, or the digitizer 1610-3 may be embedded into the display panel DP. For example, at least one of the fingerprint sensor 1610-1, the input sensor 1610-2, or the digitizer 1610-3 may be formed simultaneously through the process of forming the components (e.g., the light-emitting element, the transistor, or the like) included in the display panel DP.

In some embodiments, the sensor module 1610 may generate an electrical signal or a data value corresponding to the internal or external state of the electronic device 1000. The sensor module 1610 may further include, for example, a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illumination sensor.

The antenna module 1620 may include one or more antennas which may transmit signals or power externally or receive signals or power from an external source. According to an embodiment, the communication module 1730 may transmit and receive signals to and from an external electronic device through an antenna suitable for a communication scheme. An antenna pattern of the antenna module 1620 may be integrated into a component of the display device 1 (e.g., the display panel DP) or the input sensor 1610-2.

The audio output module 1630 may be a device which outputs audio signals to a source external to the electronic device 1000. The audio output module 1630 may include, for example, a speaker used for general purposes, such as multimedia playback or recording playback, and a receiver used exclusively for phone reception. According to an embodiment, the receiver may be formed integrally with or separately from the speaker. An audio output pattern of the audio output module 1630 may be integrated into the display device 1.

The camera module 1710 may capture still images and moving images. According to an embodiment, the camera module 1710 may include one or more lenses, image sensors, or image signal processors. The camera module 1710 may further include an IR camera capable of measuring the presence or absence of the user, the user's location, the user's line of sight, or the like.

The light module 1720 may provide light. The light module 1720 may include a light-emitting diode or a xenon lamp. The light module 1720 may operate in conjunction with the camera module 1710 or may operate independently.

The communication module 1730 may support establishment of a wired or wireless communication channel between the electronic device 1000 and the external electronic device 1020 and may support performance of communication through the established communication channel. The communication module 1730 may include one or more wireless communication modules (e.g., a cellular communication module, a short-range wireless communication module, or a global navigation satellite system (GNSS) communication module) and one or more wired communication module (e.g., a local area network (LAN) communication module or a power line communication module). The communication module 1730 may communicate with the external electronic device 1020 over a short-range wireless communication network (e.g., Bluetooth, wireless fidelity (WiFi) direct, or infrared data association (IrDA)), or a long-range wireless communication network (e.g., a cellular network, the Internet, or a computer network (e.g., a LAN or a wide area network (WAN)). Various types of the communication module 1730 described above may be implemented as a single chip or separate chips.

The input module 1300, the sensor module 1610, the camera module 1710, and the like may be used to control the operation of the display device 1 in conjunction with the processor 1100.

The processor 1100 may output commands or data to the display device 1, the audio output module 1630, the camera module 1710, or the light module 1720, based on input data received from the input module 1300. For example, the processor 1100 may generate image data in response to input data provided through the computer mouse or the active pen/stylus and output the image data to the display device 1, or may generate command data in response to input data and output the command data to the camera module 1710 or the light module 1720. In embodiments where no input data is received from the input module 1300 for a certain time, the processor 1100 may switch the operation mode of the electronic device 1000 to a low power mode or a sleep mode so as to reduce power consumption of the electronic device 1000.

The processor 1100 may output commands or data to the display device 1, the audio output module 1630, the camera module 1710, or the light module 1720, based on sensing data received from the sensor module 1610. For example, the processor 1100 may compare authentication data provided by the fingerprint sensor 1610-1 with authentication data stored in the memory 1200 and execute an application based on a comparison result. The processor 1100 may execute commands or output corresponding image data to the display device 1, based on sensing data detected by the input sensor 1610-2 or the digitizer 1610-3. In embodiments where the temperature sensor is included in the sensor module 1610, the processor 1100 may receive temperature data related to the measured temperature from the sensor module 1610 and further perform luminance correction or the like on the image data, based on the temperature data.

The processor 1100 may receive, from the camera module 1710, measurement data related to the presence or absence of the user, the user's location, the user's line of sight, or the like. The processor 1100 may further perform luminance correction or the like on the image data, based on the measurement data. For example, the processor 1100 which determines the presence or absence of the user through input from the camera module 1710 may output, to the display device 1, image data in which luminance is corrected through the data conversion circuit 1120-2 or the gamma correction circuit 1120-3.

Some of the components described above may be connected to each other through a communication scheme between peripheral devices (e.g., a bus, a general-purpose input/output (GPIO), a serial peripheral interface (SPI), a mobile industry processor interface (MIPI), or an ultra path interconnect (UPI) link) and may exchange signals (e.g., commands or data) with each other. The processor 1100 may communicate with the display device 1 through a prearranged interface. For example, the processor 1100 may use any one of the communication schemes described above. However, the disclosure is not necessarily limited thereto.

The electronic device 1000 according to embodiments may be various types of devices. The electronic device 1000 may include, for example, at least one of portable communication devices (e.g., smartphones), computer devices, portable multimedia devices, portable medical devices, cameras, wearable devices, or home appliances. The electronic device 1000 according to an embodiment is not necessarily limited to the devices described above.

According to embodiments, a light control member including a lens part with a high inclination angle may be manufactured by making an internal pressure of a chamber a high vacuum within a short period of time and curing the lens part of the light control member.

Furthermore, according to embodiments, a display device with improved light efficiency may be manufactured by including a lens part with a high inclination angle.

However, the effects of the disclosure are not necessarily limited to those described above and may be expanded in various ways without departing from the spirit and scope of the disclosure.

Each of the embodiments described above may be implemented independently, however, in some embodiments, the structure of each of the embodiments may be applied in combination to other embodiments.

Specific examples described in the disclosure are embodiments, which do not necessarily limit the scope of the embodiments. In some embodiments, when there is no specific mention such as "essential" or "important," it may not be a necessary component for the application of the disclosure.

The use of the term "the" and similar demonstratives in the specification of the embodiments (in particular, the claims) is to be construed to cover both the singular and the plural. In addition, when a range is described in the embodiments, it includes the invention to which individual values within the range are applied (unless otherwise indicated herein). This is the same as stating each individual value constituting the above range in the detailed description. Finally, operations constituting methods according to embodiments may be performed in any suitable order unless otherwise indicated herein or otherwise clearly contradicted by context. The embodiments are not necessarily limited by the order of description of operations.

Those skilled in the art will recognize that the present disclosure can be practiced in other specific ways without departing from its technical spirit or essential characteristics. Therefore, the described embodiments should be regarded as illustrative rather than being restrictive in all aspects. Although embodiments of the present disclosure have been described with reference to the accompanying drawings, the disclosure is not limited to these embodiments and may be implemented in various forms.

What is claimed is:

1. A method of manufacturing a light control member, the method comprising: forming a preliminary lens portion by disposing a lens solution on a base layer;
transferring the base layer on which the preliminary lens portion is formed to a chamber; and
forming a lens portion on the base layer by reducing an internal pressure of the chamber to not more than a pressure value for a time period, wherein the time period is preset.

2. The method of claim 1, wherein the time period is less than or equal to 100 seconds.

3. The method of claim 1, wherein the pressure value is about 10⁻⁵ torr.

4. The method of claim 1, wherein the forming of the lens portion comprises curing the preliminary lens portion by providing light of a wavelength band on the preliminary lens portion while the internal pressure of the chamber is maintained at not more than the pressure value.

5. The method of claim 1, wherein the forming of the lens portion is performed within a temperature range of about 25 °C to about 100 °C.

6. The method of claim 1, wherein the lens portion has a semicircular shape.

7. The method of claim 1, wherein the forming of the preliminary lens portion comprises spraying the lens solution onto the base layer by using inkjet printing.

8. The method of claim 1, wherein the lens solution comprises a solvent and a base resin.

9. The method of claim 8, wherein the base resin comprises at least one of polyurethane-based resin, polyester-based resin, polyvinyl chloride-based resin, polyvinyl acetate-based resin, cellulose-based resin, polyamide-based resin, polypropylene-based resin, polystyrene-based resin, or acrylic-based resin, wherein the acrylic-based resin includes at least one of polymethyl methacrylate, polyhydroxyethylmethacrylate, or polycyclohexyl methacrylate.

10. The method of claim 8, wherein the solvent comprises an ester-based compound.

11. The method of claim 8, wherein a boiling point of the solvent is between 100 °C and 300 °C.

12. The method of claim 8, wherein the lens solution further comprises at least one of TiO₂ ZrO₂ ZnO, Al₂O₃ or SiO₂.

13. A method of manufacturing a display device, the method comprising: preparing a display panel comprising an emission area and a non-emission area adjacent to the emission area; and
forming a light control member on the display panel, wherein the light control member overlaps the emission area,
wherein the forming of the light control member comprises:
forming a preliminary lens portion by disposing a lens solution on a base layer;
transferring the base layer on which the preliminary lens portion is formed to a chamber; and
forming a lens portion on the base layer by reducing an internal pressure of the chamber to not more than a pressure value for a time period, wherein the time period is preset.

14. The method of claim 13, wherein the time period is less than or equal to 100 seconds.

15. The method of claim 13, wherein the pressure value is about 10⁻⁵ torr.

16. The method of claim 13, wherein the lens portion has a semicircular shape.

17. The method of claim 13, wherein the forming of the preliminary lens portion comprises spraying the lens solution onto the base layer by using inkjet printing.

18. The method of claim 13, wherein the lens solution comprises a solvent and a base resin, and
wherein a boiling point of the solvent is between 100 °C and 300 °C.

19. The method of claim 18, wherein the lens solution further comprises at least one of TiO₂ ZrO₂ ZnO, Al₂O₃ or SiO₂.

20. An electronic device, comprising:
a controller configured to generate a scan input signal;
a power module configured to generate a scan input voltage; and
a display panel including a display area and a peripheral area adjacent to the display area, the display area including a pixel circuit;
a scan driver disposed in the peripheral area and configured to receive the scan input signal and the scan input voltage, and output a scan signal to the pixel circuit; and
a light control member including a lens portion, wherein the lens portion is formed by curing a lens solution on a base layer in a pressurized chamber for a preset time period prior to its placement in the light control member.
